(19) United States
(12) Patent Application Publication
(10) Pub. No.: US 2024/0019301 A1
(43) Pub. Date: Jan. 18, 2024

(54) OPTICAL SENSING ARRANGEMENT, AMBIENT LIGHT SENSOR AND METHOD FOR PROVIDING AN OUTPUT COUNT

(71) Applicant: ams Sensors Germany GmbH, Jena (DE)

(72) Inventors: Ravi Kumar ADUSUMALLI, Telangana (IN); Rahul THOTTATHIL, TELANGANA (IN)

(73) Assignee: ams Sensors Germany GmbH, Jena (DE)

(21) Appl. No.: 18/256,235

(22) PCT Filed: Nov. 11, 2021
(86) PCT No.: PCT/EP2021/081318

§ 371 Date: Jun. 7, 2023

(30) Foreign Application Priority Data
Dec. 10, 2020 (DE) 102020132969.5

(51) Int. Cl. G01J 1/46; G01J 1/42

(52) U.S. Cl. CPC G01J 1/46; G01J 1/4204; G01J 2001/446

(57) ABSTRACT

In one embodiment an optical sensing arrangement includes a first sensor configured to provide a first sensor signal, a second sensor configured to provide a second sensor signal, an integration unit including a first input which is connected to the first sensor, a second input which is connected to the second sensor, a first output which is configured to provide a first integration signal as a function of the first sensor signal, and a second output which is configured to provide a second integration signal as a function of the second sensor signal, a comparing unit including a first input which is connected to the first output of the integration unit, a second input which is connected to the second output of the integration unit and an output configured to provide a comparison signal as a function of the first and the second integration signal, and a control unit including a first input which is coupled to the output of the comparing unit, wherein the control unit is configured to evaluate pulses of the comparison signal and therefrom provide an output count indicative of a difference between the first and the second sensor signal

### CROSS-REFERENCE TO RELATED APPLICATIONS

The present application is the national stage entry of International Patent Application No. PCT/EP2021/081318, filed on Nov. 11, 2021, and published as WO 2022/122288 A1 on Jun. 16, 2022, which claims priority to German Application No. 10 2020 132 969.5, filed on Dec. 10, 2020, the disclosures of all of which are incorporated by reference herein in their entireties.

### FIELD OF THE INVENTION

The invention relates to the field of ambient light sensing. Specifically, the application is directed to an optical sensing arrangement, an ambient light sensor and a method for providing an output count.

### BACKGROUND OF THE INVENTION

Ambient light sensing, ALS, is widely employed in different kind of displays of devices, like smartphones and notebooks, for detecting brightness in substantially the same way as human eyes. For this, a spectral sensitivity of an ALS sensor is prepared to reproduce a photopic and/or scotopic luminosity curve of human eyes. The standard international unit for the illuminance of ambient light is the lux. Information provided by an ALS sensor is used in the device, for instance, to appropriately dim the device's screen to match the ambient light condition.

It has been found that infrared, IR, components in ambient light deteriorate a measurement result of an ALS sensor. In state of the art implementations this is resolved by providing a separate channel for sensing the IR components. The IR components are subsequently removed from the wanted signal. In detail, a first photodiode for detecting white light is connected to one ALS channel and a second diode for detecting IR light is connected to a second ALS channel. Each photocurrent is separately integrated on a feedback capacitor of an operational amplifier. Each resultant voltage is compared to a reference voltage by means of a comparator, which triggers a connected counter. Each channel consequently provides a count equivalent to the amount of light detected in said channel. In order to get the IR compensated clear count, the IR count is subtracted from the clear count in the digital domain. This solution, however, consumes a considerable amount of chip area and power.

It is therefore an objective to provide an optical sensing arrangement, an ambient light sensor and a method for providing an output count which resolve at least some of the shortcomings of the prior art described above.

The objective is achieved by the subject matter of the independent claims. Further developments and embodiments are defined in dependent claims.

The definition of terms provided in the above also applies to the following description unless stated otherwise.

### SUMMARY OF THE INVENTION

In one embodiment an optical sensing arrangement comprises a first sensor, a second sensor, an integration unit, a comparing unit and a control unit. The first sensor is configured to provide a first sensor signal. The second sensor is configured to provide a second sensor signal. The integration unit comprises a first input which is connected to the first sensor, a second input which is connected to the second sensor, a first output which is configured to provide a first integration signal as a function of the first sensor signal, and a second output which is configured to provide a second integration signal as a function of the second sensor signal. The comparing unit comprises a first input which is connected to the first output of the integration unit, a second input which is connected to the second output of the integration unit and an output. The output of the comparing unit is configured to provide a comparison signal as a function of the first and the second integration signal. The control unit comprises a first input which is coupled to the output of the comparing unit. The control unit is configured to evaluate pulses of the comparison signal and provide an output count therefrom, which output count is indicative of a difference between the first sensor signal and the second sensor signal.

The first sensor generates the first sensor signal. The second sensor generates the second sensor signal. The integration unit integrates the first signal and provides the first integration signal therefrom. The integration unit furthermore integrates the second sensor signal and provides the second integration signal therefrom. The comparing unit compares the first integration signal with the second integration signal and provides the comparison signal therefrom. The control unit evaluates pulses of the comparison signal and provides the output count therefrom, wherein the output count is indicative of or proportional to the difference between the first sensor signal and the second sensor signal.

The proposed optical light sensing arrangement just needs one integration unit and one comparing unit for providing an output count representing the difference between the first sensor signal and the second sensor signal. Thereby, area consumption and power consumption are greatly reduced when compared to the state of the art as described above.

In a development, the first sensor comprises a first photodiode which is configured to detect light in a first wavelength range. The second sensor comprises a second photodiode which is configured to detect light in a second wavelength range which at least partially overlaps the first wavelength range.

The output count is consequently indicative of a difference between the first and the second wavelength range.

For example, the first range spans a range of electromagnetic radiation, for example, the visible range of electromagnetic radiation. In particular the first photodiode is configured to detect a broadband light, e.g. clear light, or broadband white light. Typically, said first range of wavelengths also extends into the near infrared or infrared light, because photodiodes may have sensitivity in this range, too. The second photodiode is configured to detect infrared light, for example.

For example, the first sensor signal represents the amount of white light being incident on the optical sensor arrangement and near infrared and infrared light components, whereas the second sensor signal represents the amount of infrared light being incident on the optical sensing arrangement. The output count is consequently indicative of a difference between the amount of white light and the amount of infrared light being incident on the optical sensing arrangement. It may be referred to as an IR compensated output count or as an IR corrected output count.

In a development the second integration signal is inverse proportional to the first integration signal.

This means that an amplitude of the first integration signal is substantially the same as the amplitude of the second integration signal, while a slope of the first integration signal is inverse proportional to a slope of the second integration signal. The integration unit consequently provides, at its first and second outputs, a difference of the first and a second integration signal which is a function of the difference between the first and the second sensor signal.

In a development, the integration unit comprises a differential operational amplifier, a first integration capacitor and a second integration capacitor. The differential operational amplifier comprises a first input connected to the first input of the integration unit, a second input connected to the second input of the integration unit, a first output connected to the first output of the integration unit, and a second output connected to the second output of the integration unit. The first integration capacitor is coupled between the first output and the first input of the differential operational amplifier in a first feedback loop. The second integration capacitor is coupled between the second output and the second input of the differential operational amplifier in a second feedback loop.

The operational amplifier employed in the integration unit may also be referred to as a fully differential operational amplifier.

In a development the control unit further comprises a second input which is configured to receive a first clock signal, a third input which is configured to receive a second clock signal, and a first output which is configured to provide a first control signal. The first control signal is a function of the first clock signal and the comparison signal.

In a development the control unit further comprises a second output which is configured to provide a second control signal, which is inverse to the first control signal.

The second control signal may also be referred to as the inverted first control signal.

In a development the control unit further comprises a delay unit and a logic unit. The delay unit is configured to provide a delayed comparison signal from the comparison signal according to the first clock signal. The logic unit is configured to generate a first internal clock signal as a function of the first clock signal and to provide the first control signal and the second control signal using the first internal clock signal and the delayed comparison signal.

All signals are provided by the control unit according to a synchronous clocking scheme depending on the first clock signal.

In a development the logic unit is further configured to determine the output count in dependence on a number of pulses provided by the comparison signal during a measurement period which is defined by the first clock signal.

In a development the optical sensing arrangement further comprises a sampling unit which comprises a first sampling capacitor, a second sampling capacitor and a switching unit. The switching unit is configured to operate the optical sensing arrangement in one of two operation modes under control of the control unit and depending on the first and the second clock signal. The two operation modes comprise a sampling mode and a transfer mode.

It is thereby assured that the input common mode is kept at a suitable level for correct operation of the first and the second sensors.

In a development during the sampling mode a first terminal of the first sampling capacitor and a first terminal of the second sampling capacitor is respectively connected via the switching unit to a first reference potential terminal, a second terminal of the first sampling capacitor is connected via the switching unit to either a second reference potential terminal or a third reference potential terminal, and a second terminal of the second sampling capacitor is connected via the switching unit to either a fourth reference potential terminal or to the third reference potential terminal. During the transfer mode the first terminal of the first sampling capacitor is connected via the switching unit to the first input of the integration unit, the first terminal of the second sampling capacitor is connected via the switching unit to the second input of the integration unit, and the second terminal of the first sampling capacitor and the second terminal of the second sampling capacitor is respectively connected via the switching unit to the third reference potential terminal.

During the sampling phase, reference voltages which are present at the different reference voltage terminals will get sampled on the first and the second sampling capacitor, respectively. In the transfer mode the sampled voltages will get transferred to the first and the second integration capacitor, respectively. The number of times the output of the comparing unit toggles during the measurement period represents the output count.

In a development a first reference potential which is supplied to the first reference potential terminal is lower than a second reference potential which is supplied to the second reference potential terminal and is lower than a third reference potential which is supplied to the third reference potential terminal and is lower than a fourth reference potential which is supplied to the fourth reference potential terminal. The third reference potential amounts to half of the sum of the second and the fourth reference potential.

In other words, the third reference potential amounts to an average of the second and the fourth reference potential.

In one embodiment an ambient light sensor comprises the optical sensing arrangement as defined above. The first sensor comprises the first photodiode configured to detect white light, while the second sensor comprise a second photodiode configured to detect infrared light. The ambient light sensor is configured to provide the output count which is proportional to an intensity of ambient light being incident on the ambient light sensor without infrared light components.

The proposed ambient light sensor thereby needs just one channel for providing the IR-compensated output count. It thereby saves area and power when compared with state of the art implementations. The ambient light sensor may also be denoted a difference differential ambient light sensor.

In one embodiment a method for providing an output count comprises the steps of

generating, by a first sensor, a first sensor signal;

generating, by a second sensor, a second sensor signal;

integrating, by an integration unit, the first sensor signal and providing therefrom a first integration signal;

integrating, by the integration unit, the second sensor signal and providing therefrom a second integration signal;

comparing, by a comparing unit, the first integration signal with the second integration signal and providing therefrom a comparison signal;

evaluating, by a control unit, pulses of the comparison signal and providing therefrom the output count which is indicative of a difference between the first and the second sensor signal.

The output count is directly provided by means of a single integration unit and a single comparing unit. In the case that a clear photodiode is used to implement the first sensor and an IR photodiode is used to implement the second sensor, the output count represents an IR-compensated output count, thereby representing the wanted signal of an ambient light sensor.

The method may be implemented, for example, by the optical sensing arrangement as defined above.

### BRIEF DESCRIPTION OF THE DRAWINGS

The text below explains the proposed optical sensing arrangement and ambient light sensor in detail using exemplary embodiments with reference to the drawings. Components and circuit elements that are functionally identical or have the identical effect bear identical reference numbers. In so far as circuit parts or components correspond to one another in function, a description of them will not be repeated in each of the following figures. Therein,

FIG. 1 shows an exemplary embodiment of the optical sensing arrangement as proposed;

FIG. 2 shows exemplary signal diagrams for the embodiment of FIG. 1;

FIG. 3 shows exemplary signal diagrams for the embodiment of FIG. 1;

FIG. 4 shows simulation results of the embodiment of FIG. 1; and

FIG. 5 shows an exemplary embodiment of the ambient light sensor as proposed.

### DETAILED DESCRIPTION

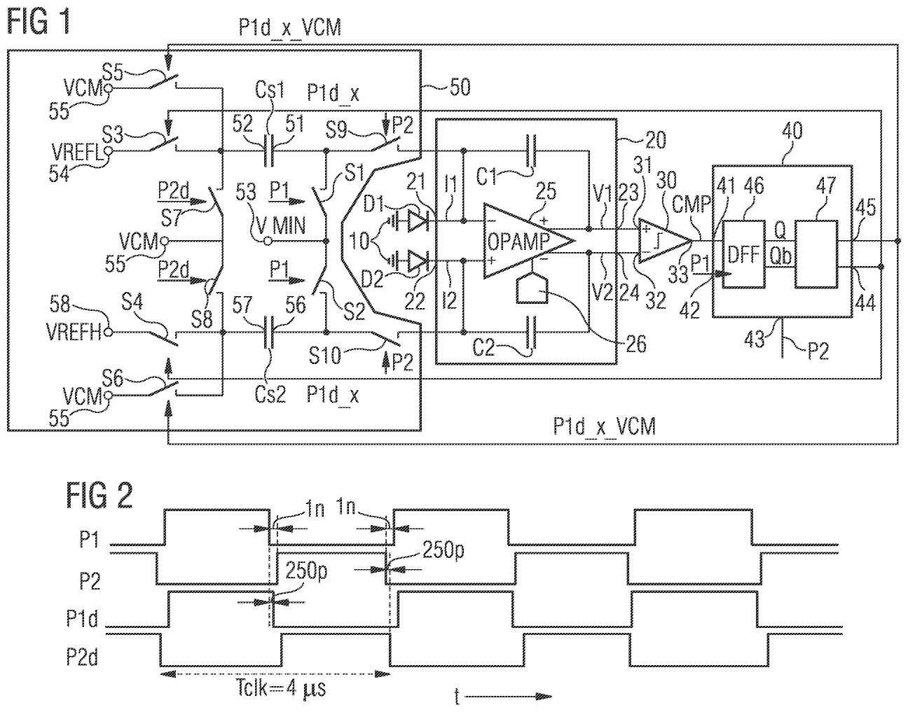

FIG. 1 shows an exemplary embodiment of an optical sensing arrangement as proposed. The optical sensing arrangement comprises a first sensor D1, a second sensor D2, an integration unit 20, a comparing unit 30 and a control unit The integration unit 20 has a first input 21, a second input 22, a first output 23 and a second output 24. The first sensor D1 comprises a first photodiode which is configured to detect white light. The second sensor D2 comprises a second photodiode which is configured to detect infrared light. The first photodiode D1 is connected with its anode terminal to a reference potential terminal 10 and with its cathode terminal to the first input 21 of the integration unit 20. The second photodiode D2 is connected with its anode terminal to the reference potential terminal 10 and with its cathode terminal to the second input 22 of the integration unit 20. The comparing unit 30 has a first input 31, a second input 32, and an output 33. The first output 23 of the integration unit 20 is coupled to the first input 31 of the comparing unit 30. The second output 24 of the integration unit is coupled to the second input 32 of the comparing unit 30. The control unit 40 has a first input 41 which is coupled to the output 33 of the comparing unit 30.

The first sensor D1, i.e. the first photodiode, generates a first sensing signal I1. The second sensor D2, i.e. the second photodiode, generates a second sensor signal I2. The integration unit 20 integrates the first sensor signal I2 and provides therefrom a first integration signal V1. The integration unit also integrates the second sensor signal I2 and provides therefrom a second integration signal V2 at its second output 24. The comparing unit 30 compares the first integration signal V1 present at its first input 31 with the second integration signal V2 at its second input 32 and provides therefrom a comparison signal CMP at its output 33. The control unit 40 receives the comparison signal CMP at its first input 41, evaluates pulses of said comparison signal CMP and provides therefrom an output count which is indicative of a difference between the first sensor signal I1 and the second sensor signal I2.

The first photodiode of the first sensor D1 is configured to detect white light. The second photodiode of the second sensor D2 is configured to detect infrared light. The output count is consequently indicative of a difference between white light and infrared light sensed or experienced by the optical sensing arrangement.

In an exemplary implementation, the first photodiode essentially is sensitive between approximately 300 nm and approximately 700 nm, basically known as the visible range, however, the first photodiode also detects portions of infrared light as known to those skilled in the art. The second photodiode essentially is sensitive between approximately 800 nm and approximately 1000 nm, i.e. the infrared range.

The optical sensing arrangement as proposed is consequently able to provide the output count representing light surrounding the optical sensing arrangement without infrared light components by means of just one integration unit and just one comparing unit, i.e. by just one channel. This greatly reduces the area of the proposed circuit. At the same time power consumption is reduced.

The integration unit 20 comprises a differential operational amplifier 25, a first integration capacitor C1 and a second integration capacitor C2. The operational amplifier 25 comprises a first input which is connected, for example directly, to the first input 21 of the integration unit 20. The operational amplifier 25 further has a second input which is connected, for example directly, to the second input 22 of the integration unit 20. Therein, the first input of the operational amplifier 25 may be an inverting input, while the second input of the operational amplifier 25 may be a non-inverting input. The first integration capacitor C1 is coupled between the first output and the first input of the operational amplifier 25 in a first feedback loop. The second integration amplifier C2 is coupled between the second output and the second input of the operational amplifier 25 in a second feedback loop.

The integration unit 20 may further comprise a digital-to-analog converter 26 for auto zeroing of the operational amplifier 25 as known by those skilled in the art. The first sensor signal I1, as well as the second sensor signal I2 may each comprise a current signal. The current of the first sensor signal I1 is integrated to the first integration capacitor C1. Therefrom, the first integration signal V1 is provided in the form of a voltage signal at the first output 23 of the integration unit 20. Likewise, the current of the second sensor signal I2 is integrated to the second integration capacitor C2 and therefrom the second integration signal V2 is provided at the second output 24 of the integration unit 20 in the form of a voltage signal. The first output 23 of the integration unit 20 is non-inverting, while the second output of the integration unit 20 is inverting. Therein, the second integration signal V2 is inverse proportional to the first integration signal V1, i.e. the voltage signals V1 and V2 have substantially the same amplitude, and slopes that are inverse proportional to each other.

The comparison unit 30 comprises a comparator, wherein the first input 33 is realized, for instance, as a non-inverting input and receives the first integration signal V1. The second input of the comparator represents the second input 32 of the comparing unit 30 and is realized, for instance, as an inverting input for receiving the second integration signal V2. The comparator of the comparing unit 30 triggers each time the first integration signal V1 surpasses a level of the second integration signal V2. This is represented as one impulse of the comparison signal CMP.

The control unit 40 comprises a delay unit 46 and a logic unit 47. In the depicted exemplary embodiment the delay unit 46 comprises a delay flipflop, D-flipflop 46, wherein a d-input of the D-flipflop of the delay unit 46 represents the first input 41 of the control unit 40. The delay unit 46 further has a clock input which is configured to receive a first clock signal P1. Said clock input represents the second input 42 of the control unit 40. The control unit 40 further has a third input 43 which is configured to receive a second clock signal P2. The control unit 40 also has a first output 44 which is configured to provide a first control signal P1d_x. The comparison signal CMP, i.e. each impulse of the comparison signal CMP, is latched in dependence on the first clock signal P1 by the D-flipflop of the delay unit 46 to its non-inverting output as the delayed comparison signal Q. At the inverting output of the delay unit 46 an inverted delayed comparison signal Qb is also provided. The logic unit 47 receives the delayed comparison signal Q and the first clock signal P1. The logic unit 47 is configured to generate a first internal clock signal P1d by delaying the first clock signal P1 by an adjustable amount of time, for example by 250 picoseconds. The logic unit 47 is further configured to generate the first control signal P1d_x by way of a logical AND combination of the delayed comparison signal Q with the first internal clock signal P1d. The logic unit 47 is further configured to generate a second control signal P1d_x_VCM by way of a logical AND combination of the inverted delayed comparison signal Qb with the first internal clock signal P1d and provide said signal at the second output 45 of the control unit 40. Consequently, the second control signal P1d_x_VCM is inverse to the first control signal P1d_x.

The logic unit 47 is further configured to determine the output count depending on a number of pulses provided by the comparison signal CMP during a measurement period which is defined by the first clock signal P1.

The optical sensing arrangement further comprises a sampling unit 50 which comprises a first sampling capacitor Cs1, a second sampling capacitor Cs2, and a switching unit S1, S2, S3, S4, S5, S6, S7, S8, S9, S10. The switching unit S1 to S10 is configured to operate the optical sensing arrangement in one of two modes under control of the control unit 40 and depending on the first and the second clock signal P1, P2. The two operation modes comprise a sampling mode and a transfer mode. In the depicted exemplary embodiment, the switching unit S1 to S2 comprises ten switches S1, S2, S3, S4, S5, S6, S7, S8, S9, S10.

In more detail, a first switch S1 is arranged between a first terminal 51 of the first sampling capacitor Cs1 and a first reference potential terminal 53. A second switch S2 is arranged between the first reference potential terminal 53 and a first terminal 56 of the second sampling capacitor Cs2. Switches S1 and S2 are both controlled by the first clock signal P1. A third switch S3 is arranged between a second terminal 52 of the first sampling capacitor Cs1 and a second reference potential terminal 54. A fourth switch S4 is arranged between a second terminal 57 of the second sampling capacitor Cs2 and a fourth reference potential terminal 58. Switches S3 and S4 are both controlled by the first control signal P1d_x. A switch S5 is arranged between the second terminal 52 of the first sampling capacitor Cs1 and the third reference potential terminal 55. A switch S6 is arranged between the second terminal 57 of the second sampling capacitor Cs2 and the third reference potential terminal 55. Switches S5 and S6 are both controlled respectively by the second control signal P1d_x_VCM.

A switch S7 is arranged between the second terminal 52 of the first sampling capacitor Cs1 and the third reference potential terminal 55. A switch S8 is arranged between the second terminal 57 of the second sampling capacitor Cs2 and the third reference potential terminal 55. Switches S7 and S8 are both controlled by a delayed second clock signal Ptd which is a delayed version of the second clock signal P2. Said delay amounts to several hundreds of picoseconds, e.g. 100 to 1000 ps. A switch S9 is arranged between the first terminal 51 of the first sampling capacitor Cs1 and the first input 21 of the integration unit 20. Switch S10 is arranged between the second terminal 56 of the second sampling capacitor Cs2 and the second input 22 of the integration unit Switches S9 and S10 are both operated or controlled by the second clock signal P2.

During the sampling mode the first terminal 51 of the first sampling capacitor Cs1 and the first terminal 56 of the second sampling capacitor Cs2 is respectively connected via switches S1 and S2 to the first reference potential terminal 53. The second terminal 52 of the first sampling capacitor Cs1 is connected either via switch S3 to the second reference potential terminal 54 or via switch S5 to the third reference potential terminal 55. The second terminal 57 of the second sampling capacitor Cs2 is connected either via switch S4 to the fourth reference potential terminal 58 or via switch S6 to the third reference potential terminal 55.

During the transfer mode, the first terminal 51 of the first sampling capacitor Cs1 is connected via switch S9 to the first input 21 of the integration unit 20. The first terminal 56 of the second sampling capacitor Cs2 is connected by switch S10 to the second input 22 of the integration unit 20. The second terminal 52 of the first sampling capacitor Cs1 is connected via switch S7 to the third reference potential terminal 55. Likewise, the second terminal 57 of the second sampling capacitor Cs2 is connected via switch S8 to the third reference potential terminal 55.

A first reference potential VCMIN is supplied to the first reference potential terminal 53. A second reference potential VREFL is supplied to the second reference potential terminal 54. A third reference potential VCM is supplied to the third reference potential terminal 55. A fourth reference potential VREFH is supplied to the fourth reference potential terminal 56. Therein, the third reference potential VCM amounts to half of the sum of the second and the fourth reference potential VREFL, VREFH. The first reference potential VCM is lower than the second reference potential VREFL and is lower than the third reference potential VCM. The following equation reflects the relationship amongst the reference potentials:

VCMIN<VREFL<VCM<VREFH

Wherein VCMIN represents the first reference potential VCMIN, VREFL represents the second reference potential VREFL, VCM represents the third reference potential VCM and VREFH represents the fourth reference potential VREFH.

A difference between the fourth reference potential VREFH and the third reference potential VCM is substantially equal to a difference between the third reference potential VCM and the second reference potential VREFL. Said difference is referred to as reference voltage Vref.

In an exemplary implementation the first reference potential VCMIN amounts to 100 mV, while the third reference potential VCM amounts to 900 mV. A typical value of the reference voltage Vref is 5 mV, 10 mV, or 500 mV. The value of the reference voltage can be adjusted depending on the desired sensitivity and application.

In the following more details regarding the functioning of the proposed optical sensing arrangement will be provided with reference to FIGS. 2, 3 and 4.

FIG. 2 shows exemplary signal diagrams for the exemplary embodiment of FIG. 1. From top to bottom, the following signals are depicted in relation to time t: The first clock signal P1, the second clock signal P2, the first delayed clock signal P1d and the second delayed clock signal P2d. It can be discerned that the second clock signal P2 is inverted with respect to the first clock signal P1 with an overlap which has an exemplary value of 1 nanosecond. The first delayed clock signal P1d is a delayed form of the first clock signal P1 with a delay which amounts to 250 picoseconds in the depicted example. The delayed second clock signal P2d is a delayed version of the second clock signal P2, the delay with respect to the second clock signal P2 amounts in this example to 250 picoseconds. A full clock period Tclk amounts to four microseconds in the depicted example.

A high level of the first clock signal P1 indicates the sampling mode. A high level of the second clock signal P2 indicates the transfer mode.

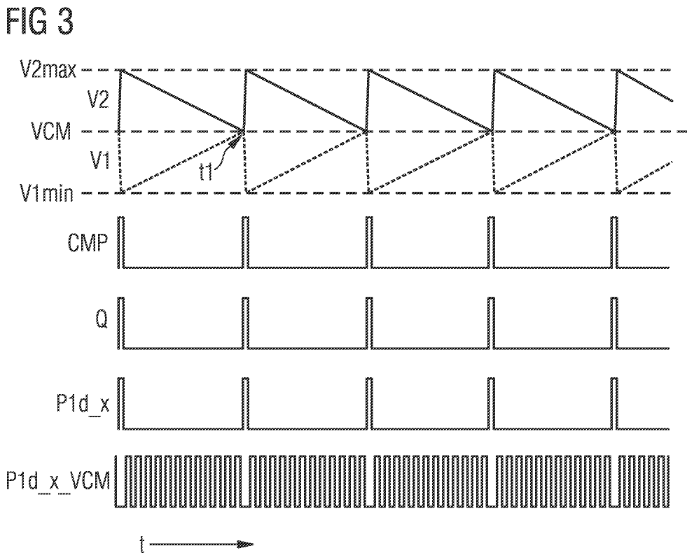

FIG. 3 shows exemplary signal diagrams for the embodiment depicted in FIG. 1. Different waveforms of the signals occurring in the optical sensing arrangement of FIG. 1 are depicted in relation to time t. The first line shows the second integration signal V2, the second line shows the first integration signal V1. The integration signals V2, V1 are symmetrical to each other with respect to the third reference potential VCM.

The third line shows the comparison signal CMP.

The fourth line shows the delayed comparison signal Q. Each time the first and the second integration signal V1, V2 cross each other, an impulse of the delayed comparison signal Q occurs.

The fifth line shows the first control signal P1d x.

The sixth line shows the second control signal P1d_x_VCM, which is inverse to the first control signal P1d_x.

The first and the second sensor D1, D2 are respectively connected by their respective cathode terminal to the first or second input 21, 22 of the integration unit 20. Said inputs are kept substantially stable at the first reference potential VCMIN, thereby representing a virtual ground. Consequently, the current generated by each of the sensors D1, D2 in the form of the first and the second sensor signal I1, I2 is always integrated to the integration capacitors C1, C2, respectively. The first integration signal V1 starts rising from a lower level V1min. Concurrently, the second integration signal V2 starts decreasing from an upper level V2max with substantially the same slope as signal V1, but in inverse proportional form.

The lower level V1min is calculated according to the following equation:

V1min=VCM−Vref*G1

Therein V1min represents the lower level V1min, VCM represents the third reference potential VCM, Vref represents the reference voltage Vref and G1 represents a first factor G1 which is calculated from the quotient of the capacitance value of the first sampling capacitor Cs1 and the capacitance value of the first integration capacitor C1.

The upper level V2max is calculated according to the following equation:

V2max=VCM+Vref*G2

Therein V2max represents the upper level V2max, VCM represents the third reference potential VCM, Vref represents the reference voltage Vref and G2 represents a second factor G2 which is calculated from the quotient of the capacitance value of the second sampling capacitor Cs2 and the capacitance value of the second integration capacitor C2.

At point-in-time t1 the first integration signal V1 reaches or surpasses the level of the second integration signal V2 leading to an impulse of the comparison signal CMP. During the sampling mode, while the first clock signal P1 is at high, the reference voltage Vref, is sampled onto the first and the second sampling capacitors Cs1, Cs2, with respect to the first reference potential VCMIN, respectively, as long as the comparison signal CMP is high. Otherwise, during the sampling mode, if the comparison signal CMP is low, the third reference potential VCM is sampled to the first and the second sampling capacitor Cs1, Cs2, respectively. Therein, the first reference potential VCMIN represents the input common mode. The third reference potential VCM represents the output common mode.

During the transfer mode, the voltage sampled respectively on the first and the second sampling capacitor Cs1, Cs2 is transferred respectively to the integration capacitors C1, C2. Thus, in the case the comparison signal CMP is at high, the first integration signal V1 is precharged to the lower level V1min, while the second integration signal V2 is precharged to the upper level V2max. Subsequently, the comparison signal CMP goes low and the first and the second sensor signals, I1, I2 are integrated onto the first and the second integration capacitor C1, C2, respectively. Thus, the first integration signal V1 rises and the second integration signal V2 decreases until the first integration signal V1 surpasses the level of the second integration signal V2 and once again, the comparison signal CMP goes to high. The number of times the comparator of the comparing unit 30 makes a decision “high”, i.e. the number of impulses of the comparison signal CMP, during a fixed measurement period provides the output count.

First and second integration capacitors C1, C2 are dimensioned with substantially equal capacitance values. First and second sampling capacitors Cs1, Cs2 are dimensioned with substantially equal capacitance values.

The time td the comparing unit 30 takes for one decision can be calculated according to the following equation:

td=2*Vref*G1,2*C1,2/(I1−I2)

Therein td represents the time td, Vref represents the reference voltage Vref, G1,2 represents the first or the second factor G1 or G2, C1,2 represents the capacitance value of the first or the second integration capacitor C1, C2, I1 represents the first sensor signal I1 and I2 represents the second sensor signal I2.

The synchronous clocking scheme which can be seen in FIG. 2 ensures that a virtual node represented by the first and second inputs 21, 22 of the integration unit 20 substantially stays at a stable value of the first reference potential VCMIN, for example, 100 mV, so that the photodiodes of the first and the second sensor D1, D2 are properly biased. Advantageously, input and output common mode voltages of the proposed optical sensing arrangement may be different. The output count is independent of the sampling frequency. Switch-induced errors, for instance of the switching unit, like charge sharing and clock feedthrough, are mitigated due to the fully differential architecture. The common mode rejection ratio, CMRR, and the power supply rejection ratio, PSRR, are improved significantly.

The signals depicted in FIG. 3 occur repeatedly during the measurement period.

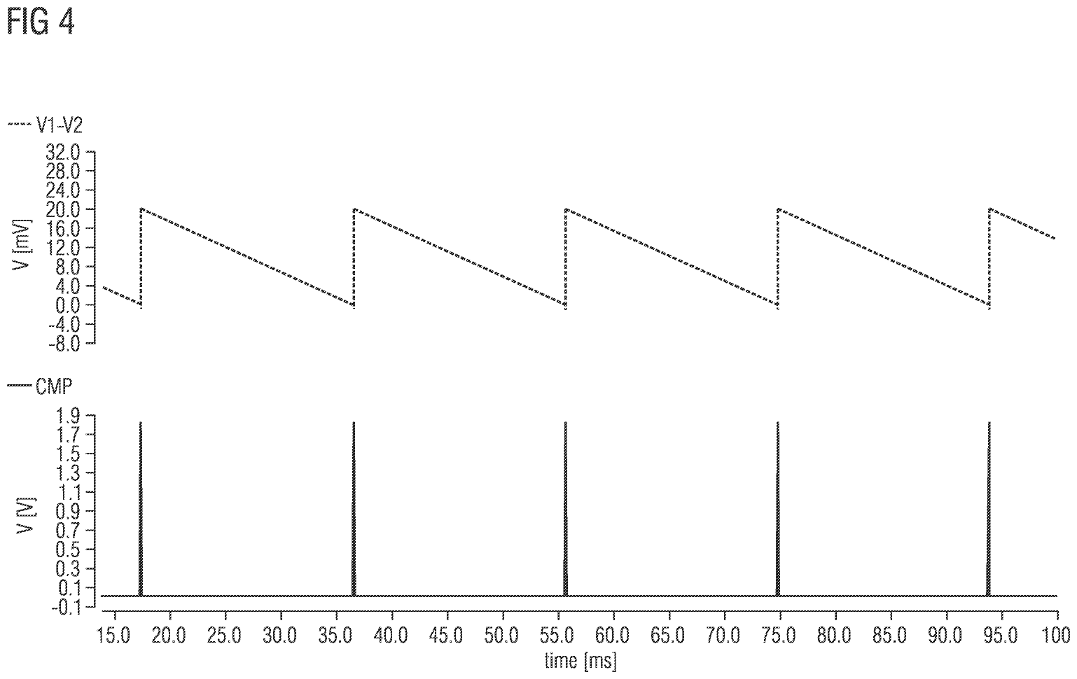

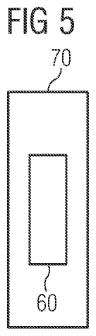

FIG. 4 shows simulation results for the proposed embodiment of FIG. 1. Transient responses are depicted. The first line shows the difference between the first and the second integration signals V1, V2 in relation to time t. The second line shows the comparison signal CMP in relation to time t.

FIG. 5 shows an exemplary embodiment of an ambient light sensor as proposed. The ambient light sensor 70 comprises an optical sensing arrangement 60. The optical sensing arrangement 60 is realized according to one of the embodiments described above.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1. An optical sensing arrangement comprising:
a first sensor configured to provide a first sensor signal,
a second sensor configured to provide a second sensor signal,
an integration unit comprising a first input which is connected to the first sensor, a second input which is connected to the second sensor, a first output which is configured to provide a first integration signal as a function of the first sensor signal, and a second output which is configured to provide a second integration signal as a function of the second sensor signal,
a comparing unit comprising a first input which is connected to the first output of the integration unit, a second input which is connected to the second output of the integration unit and an output configured to provide a comparison signal as a function of the first and the second integration signal, and
a control unit comprising a first input which is coupled to the output of the comparing unit, wherein the control unit is configured to evaluate pulses of the comparison signal and therefrom provide an output count indicative of a difference between the first and the second sensor signal,
wherein the control unit further comprises a second input which is configured to receive a first clock signal, a third input which is configured to receive a second clock signal, and a first output which is configured to provide a first control signal,
wherein the first control signal is a function of the first clock signal and the comparison signal.

2. The optical sensing arrangement according to claim 1,
wherein the first sensor comprises a first photodiode which is configured to detect light in a first wavelength range, and
wherein the second sensor (D2) comprises a second photodiode which is configured to detect light in a second wavelength range which at least partially overlaps the first wavelength range.

3. The optical sensing arrangement according to claim 1, wherein the second integration signal is inverse proportional to the first integration signal.

4. The optical sensing arrangement according to claim 1,
wherein the integration unit comprises a differential operational amplifier, a first integration capacitor and a second integration capacitor,
wherein the differential operational amplifier comprises a first input connected to the first input of the integration unit, a second input connected to the second input of the integration unit, a first output connected to the first output of the integration unit, and a second output connected to the second output of the integration unit,
wherein the first integration capacitor is coupled between the first output and the first input of the differential operational amplifier in a first feedback loop, and
wherein the second integration capacitor is coupled between the second output and the second input of the differential operational amplifier in a second feedback loop.

5. (canceled)

6. The optical sensing arrangement according to claim 1,
wherein the control unit further comprises a second output which is configured to provide a second control signal, which is inverse to the first control signal.

7. The optical sensing arrangement according to claim 1, wherein the control unit further comprises a delay unit and a logic unit, wherein the delay unit is configured to provide a delayed comparison signal from the comparison signal according to the first clock signal, and wherein the logic unit is configured to generate a first internal clock signal as a function of the first clock signal and to provide the first control signal and the second control signal using the first internal clock signal and the delayed comparison signal.

8. The optical sensing arrangement according to claim 1,
wherein the logic unit is further configured to determine the output count in dependence on a number of pulses provided by the comparison signal during a measurement period which is defined by the first clock signal.

9. The optical sensing arrangement according to claim 1,
further comprising a sampling unit which comprises a first sampling capacitor, a second sampling capacitor and a switching unit, wherein the switching unit is configured to operate the optical sensing arrangement in one of two operation modes under control of the control unit and depending on the first and the second clock signal, the two operation modes comprising a sampling mode and a transfer mode.

10. The optical sensing arrangement according to claim 9,
wherein during the sampling mode a first terminal of the first sampling capacitor and a first terminal of the second sampling capacitor is respectively connected via the switching unit to a first reference potential terminal, a second terminal of the first sampling capacitor is connected via the switching unit to either a second reference potential terminal or a third reference potential terminal, and a second terminal of the second sampling capacitor is connected via the switching unit to either a fourth reference potential terminal or to the third reference potential terminal, and
wherein during the transfer mode the first terminal of the first sampling capacitor is connected via the switching unit to the first input of the integration unit, the first terminal of the second sampling capacitor is connected via the switching unit to the second input of the integration unit, and the second terminal of the first sampling capacitor and the second terminal of the second sampling capacitor is respectively connected via the switching unit to the third reference potential terminal.

11. The optical sensing arrangement according to claim 10,
wherein a first reference potential which is supplied to the first reference potential terminal is lower than a second reference potential which is supplied to the second reference potential terminal and is lower than a third reference potential which is supplied to the third reference potential terminal and is lower than a fourth reference potential which is supplied to the fourth reference potential terminal, and
wherein the third reference potential amounts to half of the sum of the second and the fourth reference potential.

12. The optical sensing arrangement according to claim 1,
wherein the output count is provided by means of the integration unit as the single integration unit and by means of the comparing unit as the single comparing unit.

13. An ambient light sensor comprising the optical sensing arrangement according to claim 2, the ambient light sensor being configured to provide the output count which is proportional to an intensity of ambient light being incident on the ambient light sensor without infrared light components.

14. A method for providing an output count comprising:
generating, by a first sensor, a first sensor signal,
generating, by a second sensor, a second senor signal,
integrating, by an integration unit the first sensor signal and therefrom providing a first integration signal,
integrating, by the integration unit, the second sensor signal and therefrom providing a second integration signal,
comparing, by a comparing unit, the first integration signal with the second integration signal and therefrom providing a comparison signal,
evaluating, by a control unit, pulses of the comparison signal and therefrom providing the output count which is indicative of a difference between the first sensor signal and the second sensor signal, wherein the method is implemented by the optical sensing arrangement of claim 1.
